(19) United States
(12) Patent Application Publication
(10) Pub. No.: US 2010/0109744 A1
(43) Pub. Date: May 6, 2010

(54) LEVEL SHIFTER HAVING A CASCODE CIRCUIT AND DYNAMIC GATE CONTROL

(76) Inventors: Martin Czech, Eschbach (DE); Juergen Giehl, Kirchzarten (DE); Ulrich Theus, Freiburg (DE)

Correspondence Address: Patrick J. O'Shea, Esq.;O'Shea Getz P.C., Suite 912, 1500 Main Street, Springfield, MA, 01115, US

(21) Appl. No.: 12/613,959

(22) Filed: Nov. 6, 2009

(30) Foreign Application Priority Data
Nov. 6, 2008 (DE) 10 2008 056 130.4

(51) Int. Cl. H03L 5/00

(52) U.S. Cl. 327/333

(57) ABSTRACT

A level shifter for converting an input signal (in) from a first operating voltage range (I) having a first ground potential (VSS1) and a first operating potential (VDD1) into an output signal (out) in a second operating voltage range (II) having a second ground potential (VSS2) and a second operating potential (VDD2). An input circuit (1) receives the input signal and an output circuit (2) provides the output signal (out), where the input circuit includes a parallel circuit made up by a first cascode circuit and a second cascode circuit, and the first and second cascode circuits each being formed by a first transistor in the source circuit and a second transistor in the gate circuit, a dynamic control being provided for the second transistors.

### PRIORITY INFORMATION

This patent application claims priority from German Patent Application No. 10 2008 056 130.4 filed Nov. 6, 2008, which is hereby incorporated by reference in its entirety.

### BACKGROUND OF THE INVENTION

The present invention relates to electronic circuits, and in particular to level shifter circuits.

Level shifters of this type are known from the related art, for example, from German Patent DE 10 2004 052 092 A1 for converting an input signal in from a first operating voltage range I having a first ground potential VSS1 and a first supply potential VDD1 into an output signal out in a second operating voltage range II having a second ground potential VSS2 and a second supply potential VDD2.

FIGS. 3 and 4 schematically illustrate prior art level shifters.

FIG. 3 is a schematic illustration of a prior art level shifter 300 is a first input transistor T1 302 and a first output transistor T3 304 with a series circuit of a second input transistor T2 306 and a second output transistor T4 308 and is connected between first ground potential VSS1 310 and second supply potential VDD2 312. The first output transistor T3 304 and the second output transistor T4 308 are cross-coupled, i.e., a control input of the first output transistor T3 304 is connected to a junction point between the second input transistor T2 306 and the second output transistor T4 308, and a control input of the second output transistor T4 308 is connected to a junction point between the first input transistor T1 302 and the first output transistor T3 304. Input signal in on line 314 may be directly supplied to a control input of the first input transistor T1 302, while it may be supplied to a control input of the second input transistor T2 306 as an inverted input signal inq on line 316. An output signal out on line 318 may be picked off at the junction point between the second input transistor T2 and the second output transistor T4, while an inverted output signal outq on line 320 may be picked off at the junction point between the first input transistor T1 and the first output transistor T3.

If, for example, a high signal is applied on the line 314, the first input transistor T1 is switched to a conducting state and raises the downstream junction point to the first ground potential VSS1. The second input transistor T2, to which the inverted high signal, i.e., a low signal, is supplied, becomes non-conductive. The first ground potential VSS1, applied to the junction point between the first input transistor T1 and the first output transistor T3, switches the second output transistor T4, which is designed as a p-channel transistor, into a conducting state, so that the junction point between the second input transistor T2 and the second output transistor T4 is raised to the second supply potential VDD2. The potential applied to the junction point brings the first output transistor T3, which is also designed as a p-channel transistor, into a blocking state. On the output side, a high signal, namely, the second supply potential VDD2, may thus be picked off at the junction point between the second input transistor T2 and the second output transistor T4 as the output signal out on the line 318. On the output side, at the junction point between the first input transistor T1 and the first output transistor T3, a low signal, namely the first ground potential VSS1, may be picked off as inverted output signal outq on line 320.

If first operating voltage range I is in a range from 0 V to 3 V, for example, and second operating voltage range II is in a range of 7 V to 12 V, it is also necessary, as FIG. 4 shows, to replace each input transistor T1, T2 with a cascode circuit made up of first transistors T11, T21 402, 404 and second transistors T12, T22 406, 408 for surge protection. The control inputs of the second transistors T12, T22 406, 408 are connected to the first supply potential VDD1, so that the two second transistors T12, T22 406, 408 designed as n-channel transistors, are permanently in a conducting state. The two first transistors T11, T21 402, 404 are technologically designed in such a way that they do not overcome the high potential difference between the first ground potential VSS1 and the second supply potential VDD2 without being damaged. This disadvantage is eliminated by the second transistors T12, T22 406, 408.

If, in a level shifter according to the prior art, a potential difference in first operating voltage range I is so small that a resulting effective gate voltage Veff_{G} is in the proximity of threshold voltage Vₜₕ of the input transistors T11 and T21 402, 404, and no transistors having a lower threshold voltage Vₜₕ, which is achieved by a thinner gate oxide and a suitable channel doping, can be used, the level shifter known from the prior art will not operate, since the effective gate voltage of the cascode transistors T12, T22 406, 408 is no longer high enough. Effective gate voltage Veff_{G} is defined as the difference between an actually applied gate-source voltage V_{GS} and threshold voltage Vₜₕ of a transistor.

There is a need for a level shifter that operates reliably even in the case of a low potential difference in the first operating voltage range I and a high potential difference in the second operating voltage range II.

### SUMMARY OF THE INVENTION

A level shifter according to an aspect of the present invention converts an input signal from a first operating voltage range having a first ground potential and a first operating potential into an output signal in a second operating voltage range having a second ground potential and a second operating potential. The level shifter includes an input circuit and an output circuit; the input signal may be applied to the input circuit, and the output signal may be picked off at the output circuit. The input circuit includes a parallel circuit made up of a first cascode circuit and a second cascode circuit, each cascode circuit having a first transistor in the source circuit and a second transistor in the gate circuit. The level shifter includes a dynamic control for the second transistors.

By using dynamic gate control for the second transistors, the second transistors may be designed in a manufacturing process according to the requirements for the second operating voltage range. Using the dynamic gate control the second transistors may be brought into a conducting state despite a low potential difference in the first operating voltage range.

Dynamic gate control may be achieved, for example, by using a capacitor that between a control terminal of the first transistor and a control terminal of the second transistor. If a signal is applied to the first transistor, depending on the shape of the signal, charges are pushed from the capacitor to the control input of the second transistor or pulled from the control input of the second transistor to the capacitor. If a high signal is applied, the corresponding charges are thus moved from the capacitor to the control terminal of the second transistor, so that an increased potential is briefly applied there, which is sufficient to set the second transistor into a conducting state.

To prevent an excessively rapid charge leveling to the first operating potential, a resistor may be situated between the control terminal of each of the second transistors and the first operating potential. To prevent voltage-induced defects, that may occur due to an excessively high or excessively low potential at the control input of the second transistor, a clamping circuit, that clamps to the first operating potential may be situated parallel to the resistor. This clamping circuit may be implemented, for example, by using two diodes connected in antiparallel or two transistors connected as diodes.

Dynamic gate control is used preferably in level shifters in which the first transistors are suitable for the first operating voltage range and the second transistors are suitable for the second operating voltage range. The suitability of the particular transistors for the first and second operating voltage ranges determines the technological dimensioning of the particular transistors. For example, the transistors for the first operating voltage range are provided with a thinner gate oxide and a lower threshold voltage than those for the second operating voltage range. Thus, however, the result of this is that the first transistors do not overcome a high potential difference between the second supply potential and the first ground potential without being damaged. If the second transistors connected in cascode, which are designed in such a way that they overcome the potential difference in the second operating voltage range without being damaged, are provided for surge protection of the first transistors, this results in the second transistors having to be dimensioned to have a thicker gate oxide and a higher threshold voltage. Due to the dynamic gate control, an effective gate voltage may be achieved at the second transistors, which is sufficiently high for setting them into a conducting state. The effective gate voltage is defined as the difference between a gate source voltage applied to the transistor and a threshold voltage of the transistor.

To provide defined input signals and output signals for the level shifter, inverters may be provided both at the input and at the output of the level shifter.

The capacitors of the dynamic gate control may be formed, for example, by gate capacitors of MOS transistors or by metal finger capacitors or MIM capacitors. The gate capacitors of MOS transistors have the advantage that they have a high capacitor coating per surface area. Metal finger capacitors or MIM capacitors are associated with a higher surface area requirement.

The resistors of the dynamic gate control may be formed, for example, by polysilicon, diffusion resistors, or well resistors, polysilicon resistors having the advantage that they are uncoupled from the substrate.

The input circuit and/or the output circuit may have different protective circuits for protection against electrostatic damage.

For example, to prevent excessive voltages between the first ground potential and the second ground potential, a circuit comprising two clamping diodes connected in antiparallel or transistors connected as diodes may be provided. Furthermore, a potential difference in the first operating voltage range may be limited by a first operating voltage clamping circuit, and a potential difference in the second operating voltage range may be limited by a second operating voltage clamping circuit, each of which is situated between the ground potential and the supply potential. The output signal may be limited to the second operating voltage range by clamping diodes or by transistors connected as diodes, so that no damaging voltages may be applied to the output. In addition, further resistors may be situated between the input circuit and the output circuit for current limitation.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 is a schematic illustration of a level shifter having cascode circuits and a dynamic gate control;

FIG. 2 is a pictorial illustration of typical voltage curves when switching over from a low level to a high level using a level shifter according to an aspect of the present invention;

FIG. 3 is a schematic illustration of a prior art level shifter; and

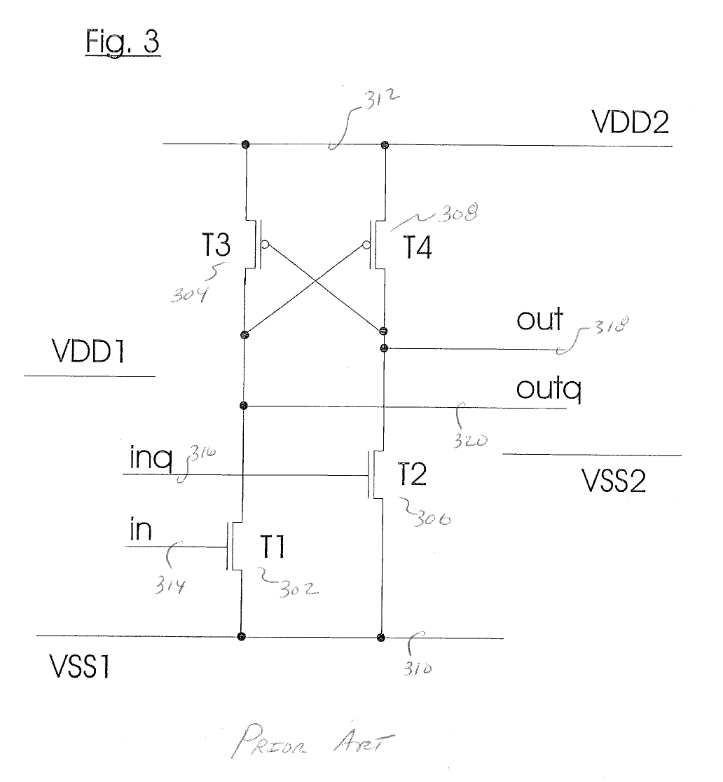

FIG. 4 is a schematic illustration of a prior art level shifter having a cascode circuit.

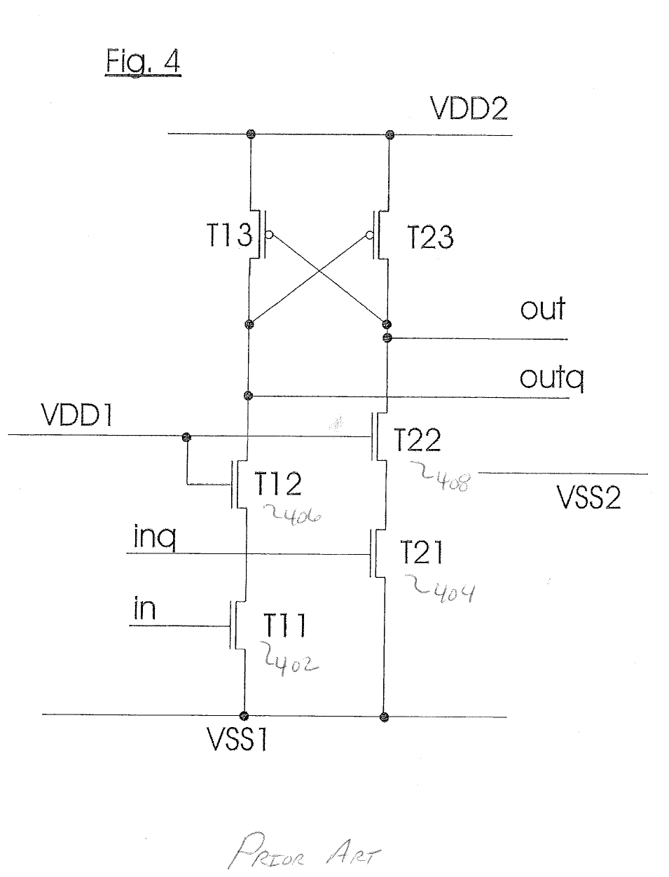

### DETAILED DESCRIPTION OF THE INVENTION

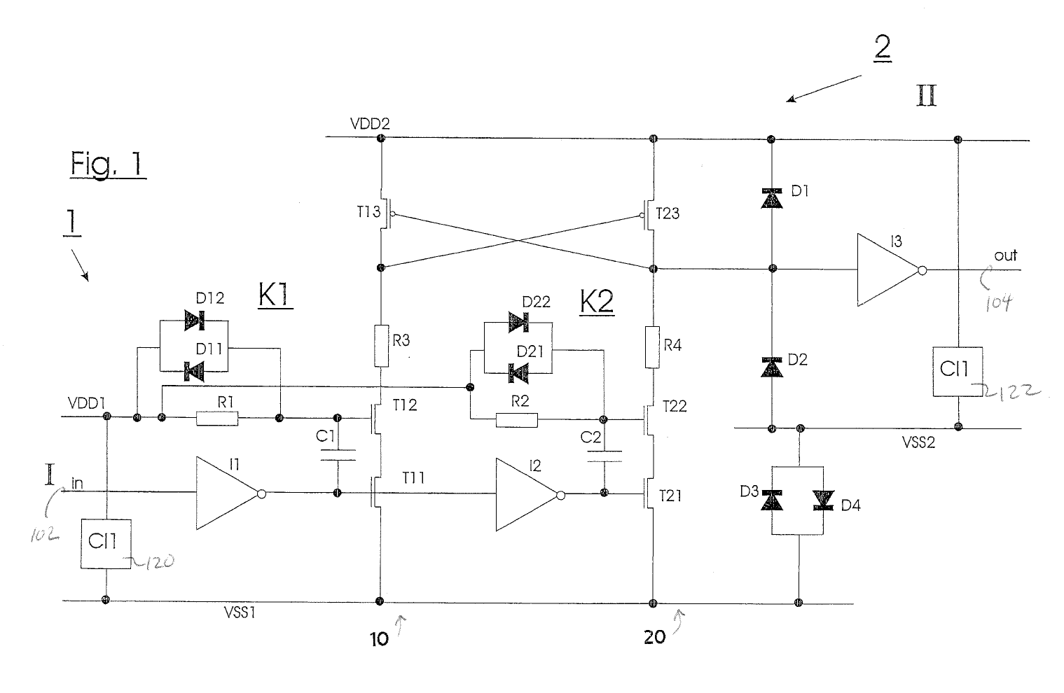

FIG. 1 is a schematic illustration of a level shifter 100 that converts an input signal in on a line 102 from a first operating voltage range I into an output signal out on a line 104 in a second operating voltage range II. The first operating voltage range I has a first ground potential VSS1 and a first operating potential VDD1. The second operating voltage range II has a second ground potential VSS2 and a second operating potential VDD2. Input circuit 1 is designed as a parallel circuit made up of a first input stage 10 and a second input stage 20, each having, as a cascode circuit, a first transistor T11, T21 in the source circuit and a second transistor T12, T22 in the gate circuit. Each input stage 10, 20 also has a dynamic gate control for controlling a control input of second transistors T12, T22. The dynamic gate control may be implemented using capacitors C1, C2, each of which is situated between a control input of the first transistor T11, T21 and the control input of the second transistor T12, T22. To prevent excessively rapid potential leveling between the control input of the second transistor T12, T22 and the first supply potential VDD1, a resistor R1, R2 is situated between the control inputs of each of the second transistors T12, T22 and first supply potential VDD1. Two diodes D11, D12, D21, D22, connected in antiparallel, are provided in parallel to resistors R1, R2 as first clamping circuit K1 and second clamping circuit K2 for clamping to first supply potential VDD1.

The input signal in on the line 102 is inverted by a first inverter I1 for first transistor T11 of the first input stage 10 and supplied inverted again, i.e., normal, by a second inverter I2, to first transistor T21 of the second input stage 20.

Resistors R3, R4 are situated between the input circuit 1 and the output circuit 2 to limit current flowing between the circuits.

The output circuit 2 is formed by two cross-coupled third transistors T13, T23, which are designed as p-channel transistors. The third transistors T13, T23 are situated in the source circuit; the output signal out on the line 104 may be picked off at the drain terminal of one third transistor T13, which is connected to the first input stage 10, and an inverted output signal outq may be picked off at the drain terminal of the other third transistor T23, which is connected to the second input stage 20. Inverted output signal outq is clamped by first clamping diode D1 and a second clamping diode D2 to second operating voltage range II, the first clamping diode D1 clamping to the first supply potential VDD2 and the second clamping diode D2 clamping to the second ground potential VSS2. The output circuit 2 is connected downstream from a third inverter I3, so that output signal out on the line 104 may be picked off at an output of the third inverter I3.

To prevent high potential differences between the first ground potential VSS1 and the second ground potential VSS2, two diodes D3, D4, connected in antiparallel, which may also be designed as MOS transistors connected as diodes, are connected between the first ground potential VSS1 and the second ground potential VSS2.

The potential differences between the ground potential VSS1, VSS2 and the supply potential VDD1, VDD2 in the particular operating voltage ranges 1, 2 are limited by appropriately situated other clamping circuits C11, C12 120, 122, which are connected to the particular ground potential VSS1, VSS2 and the particular supply potential VDD1, VDD2.

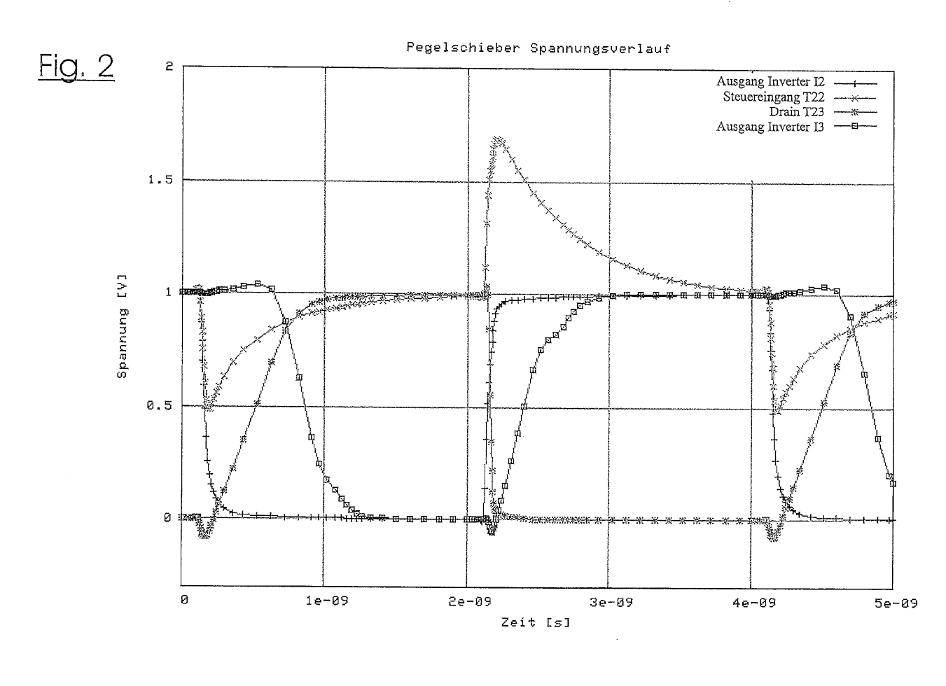

The function of the above-described level shifter is explained below with reference to the voltage curves depicted in FIG. 2 for a transition of input signal in on the line 102 from a low level to a high level as an example.

FIG. 2 shows corresponding voltage curves at the outputs of the second and third inverters I2, I3 at the control input of the second transistor T22 of the second input stage 20 and at the drain terminal of the third transistor T23. First operating voltage range I is specified as having a ground voltage of 0 V and a supply voltage of 1 V for this purpose as an example.

The output signal of the inverter I2 describes double inverted input signal in which is applied to the first transistor T21 of the second input stage 20. Inverted output signal outq, may be picked off at the drain terminal of the third transistor T23; it subsequently may be picked off at the output of the inverter I3 as output signal out.

If a transition from a low level (0 V) to a high level is present at the output of the second inverter I2, charges are pushed to the control terminal of the second transistor T22 by the capacitor C2 via the capacitive coupling. The control terminal of the second transistor T22 is normally at the first supply potential VSS1 and is briefly raised over the first supply potential VSS1 by the additional charges from the capacitor C2, whereby the second transistor T22 is set to a conducting state and, together with also conducting the first transistor T21, pulls the drain terminal of the third transistor T23 toward the first ground potential VDD1. A low level may thus be picked off at the drain terminal of the third transistor T23; this low level is converted by the third inverter I3 to a high level, which may be picked off as output signal out on the line 104.

As evident from FIG. 2, the potential at the input of the second transistor T22 is lowered below the first supply potential VDD1 by approximately 0.5 V when the input signal is switched from a high level to a low level, while the input potential of the second transistor T22 is raised by approximately 0.7 V when switching from a low level to a high level. The input potential of the second transistor is set again to the value of the first supply potential VDD1 in the form of a charge or discharge curve for the capacitor C2.

Using the above-described dynamic gate control, a gate-source voltage V_{GS} of the second transistors T12, T22 may be increased in such a way that an effective gate voltage Veff_{G} of the second transistors T12, T22 is sufficiently high for setting them into a conducting state despite a threshold voltage Vₜₕ that is elevated for technological reasons.

Although the present invention has been illustrated and described with respect to several preferred embodiments thereof, various changes, omissions and additions to the form and detail thereof, may be made therein, without departing from the spirit and scope of the invention.

What is claimed is:

1. A level shifter for converting an input signal (in) from a first operating voltage range (I) having a first ground potential (VSS1) and a first operating potential (VDD1) into an output signal (out) in a second operating voltage range (II) having a second ground potential (VSS2) and a second operating potential (VDD2), the level shifter comprising: an input circuit that receives the input signal (in) and an output circuit that provides the output signal, the input circuit having a parallel circuit comprising a first cascode circuit and a second cascode circuit, and the first and second cascode circuits each being formed by a first transistor in the source circuit and a second transistor in the gate circuit, wherein a dynamic control is provided for the second transistors.

2. The level shifter of claim 1, wherein, in the first and second cascode circuits, a capacitor is situated between a control terminal of each first transistor and a control terminal of each second transistor.

3. The level shifter of claim 2, wherein a resistor is located between the control terminal of each of the second transistors and the first operating potential (VDD1).

4. The level shifter of claim 3, wherein the control terminal of each of the second transistors clamps to the first operating potential (VDD1) with the aid of a clamping circuit.

5. The level shifter of claim 4, wherein first and second diodes are connected in antiparallel as a clamping circuit located in parallel to the control terminal of the first transistors.

6. The level shifter of claim 5, wherein the first and second diodes are implemented by MOS transistors.

7. The level shifter of claim 1, wherein the first transistors are suitable for the first operating voltage range (I), and the second transistors are suitable for the second operating voltage range (II).

8. The level shifter of claim 7, wherein a plurality of inverters are provided upstream from the input circuit and/or downstream from the output circuit

9. The level shifter of claim 2, wherein the capacitors are formed by gate capacitors of MOS transistors.

10. The level shifter of claim 2, wherein the capacitors are formed by metal finger or MIM capacitors.

11. The level shifter of claim 3, wherein the resistors are formed by polysilicon resistors.

12. The level shifter of claim 1, wherein the resistors are formed by diffusion resistors or well resistors.

13. The level shifter of claim 12, wherein the input circuit and the output circuit comprise protective circuits against electrostatic damage.

14. The level shifter of claim 12, wherein third and fourth diodes are connected in antiparallel between the first ground potential (VSS1) and the second ground potential (VSS2).

15. The level shifter of claim 14, wherein third and fourth resistors are provided between the input circuit and the output circuit for current limitation.
